(19) United States
(12) Patent Application Publication
(10) Pub. No.: US 2025/0063769 A1
(43) Pub. Date: Feb. 20, 2025

(54) RF SWITCH

(71) Applicant: STMicroelectronics International N.V., Geneva (CH)

(72) Inventors: Siddhartha DHAR, Delhi (IN); Stephane MONFRAY, Eybens (FR)

(73) Assignee: STMicroelectronics International N.V., Geneva (CH)

(21) Appl. No.: 18/804,598

(22) Filed: Aug. 14, 2024

(30) Foreign Application Priority Data
Aug. 17, 2023 (FR) 2308741

(51) Int. Cl. H01L 29/78; H01L 29/423; H01L 29/49

(52) U.S. Cl. CPC H01L 29/7843; H01L 29/42376; H01L 29/4983

(57) ABSTRACT

A transistor suited for use as an RF switch includes a semiconductor layer and a stack of a gate insulator layer and a conductive gate layer. A length of the conductive gate layer is smaller on the side of a lower surface, located in the vicinity of the gate insulator layer, and is greater on the side of an upper surface, opposite to the lower surface. Lateral sides of the conductive gate layer are covered, on a lower portion, with a first material and, on an upper portion, with a second material. The first material has a Young's modulus greater than a Young's modulus of the second material.

### PRIORITY CLAIM

This application claims the priority benefit of French Application for Patent No. 2308741, filed on Aug. 17, 2023, the content of which is hereby incorporated by reference in its entirety to the maximum extent allowable by law.

### TECHNICAL FIELD

The present disclosure generally concerns electronic components and, more particularly, field-effect transistors of Metal Oxide Semiconductor Field Effect Transistor (MOSFET) type.

### BACKGROUND

MOSFET-type transistors are field-effect transistors comprising an electrically-conductive gate insulated from a semiconductor substrate by a dielectric layer referred to as a gate insulator.

Various implementations of MOSFET transistors have already been provided.

It would be desirable to at least partly overcome certain disadvantages of known implementations of MOSFET transistors.

There is a need in the art to improve the electric performance of MOSFET transistors intended for radio frequency (RF) signal switching applications. Such transistors are referred to as RF switches.

### SUMMARY

An embodiment provides a transistor comprising, on a semiconductor layer, a stack of a gate insulator layer and of a conductive gate layer, wherein: the length of the conductive gate is smaller on the side of a lower surface, located in the vicinity of the gate insulator layer, and is larger on the side of an upper surface, opposite to the lower surface, and the lateral sides of the conductive gate layer are covered, on a lower portion, with a first material and covered, on an upper portion, with a second material, the first material having a Young's modulus greater than that of the second material.

According to an embodiment, the Young's modulus of the first material is greater than 200 GPa.

According to an embodiment, the Young's modulus of the second material is smaller than 100 GPa.

According to an embodiment, the first material has a dielectric constant greater than that of the second material.

According to an embodiment, the dielectric constant, relative with respect to 80, of the first material is greater than 7.

According to an embodiment, the dielectric constant, relative with respect to 80, of the second material is smaller than 4.

According to an embodiment, the conductive gate layer comprises a notch extending across the entire width on its lower surface side.

According to an embodiment, the difference between the length of the conductive gate layer on the lower surface side and the length of the conductive gate layer on the upper surface side is in the range from 5 nm to 40 nm.

According to an embodiment, the first material is based on nitride, on carbide, or on diamond.

According to an embodiment, the second material is based on tetraethylorthosilicate, on phosphosilicate glass, or on silicoboron carbonitride.

Another embodiment provides a radio frequency switch comprising a transistor such as described hereabove.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a cross-section view partially and schematically illustrating a transistor according to a first embodiment;

FIG. 2 is a cross-section view partially and schematically illustrating a transistor according to a second embodiment;

FIG. 3 is a cross-section view partially and schematically illustrating a transistor according to a third embodiment; and

FIG. 4 is a cross-section view partially and schematically illustrating a transistor according to a fourth embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

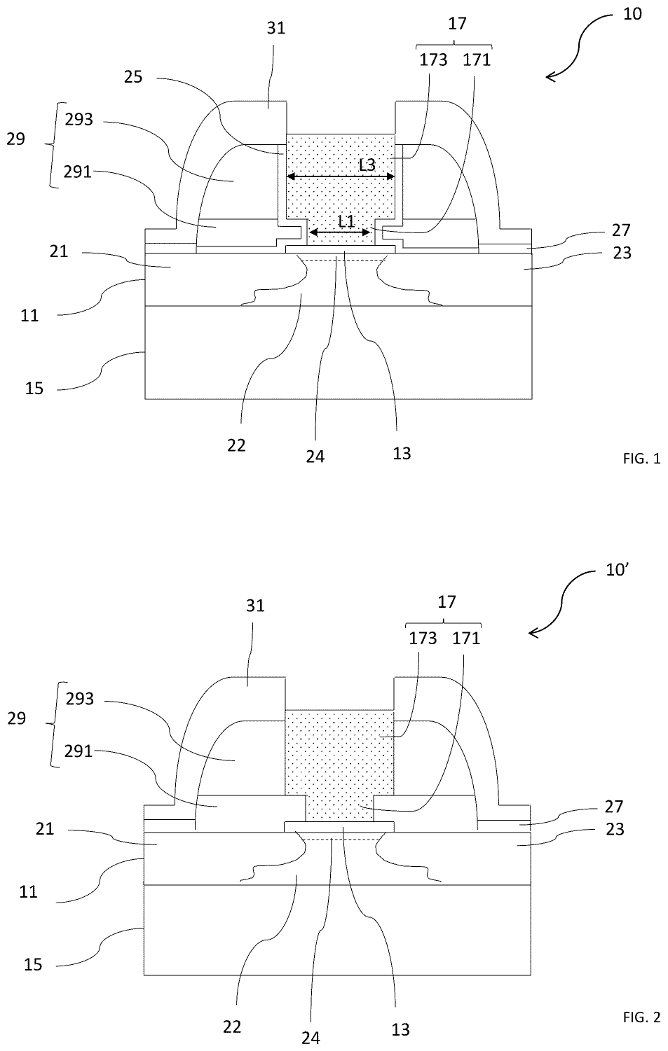

FIG. 1 is a cross-section view partially and schematically illustrating a transistor 10 according to a first embodiment.

Transistor 10 comprises a semiconductor layer 11 topped with a dielectric layer 13 also referred to as a gate insulator layer. Transistor 10 further comprises a conductive layer 17, also referred to as a conductive gate layer, on gate insulator layer 13. As an example, transistor 10 comprises a buried insulating layer 15, under semiconductor layer 11. Layers 11 and 15 correspond, for example, to a stack of layers within a substrate of the Semiconductor On Insulator (SOI) type.

As an example, in FIG. 1, semiconductor layer 11 is formed on top of and in contact with buried insulating layer 15. Gate insulator layer 13 is, for example, formed on top of and in contact with semiconductor layer 11. Conductive gate layer 17 is, for example, formed on top of and in contact with insulating layer 13.

In the embodiment of FIG. 1, conductive gate layer 17 has a length that is relatively smaller on the side of a lower surface, located in the vicinity of gate insulator layer 13, and relatively greater on the side of an upper surface, opposite to the lower surface. In this context, the reference to a “length” of a transistor corresponds to a direction extending between the source region and drain region of the transistor.

As an example, conductive gate layer 17 comprises a first portion 171 and a second portion 173, located on top of and in contact with first portion 171. The first portion 171 and second portion 173 each have, for example, different lengths. Here, the length L1 of the first portion 171 being smaller than the length L3 of the second portion 173 of conductive gate layer 17. As an example, the first portion 171 has a length L1 that is constant along its entire height. As an example, the second portion 173 has a length L3 that is constant along its entire height.

Conductive gate layer 17 thus comprises across its entire width a lengthwise notch exposing a portion of the upper surface of gate insulator layer 13. In this context, the reference to a “width” of a transistor corresponds to a direction extending parallel to each of the source region and drain region of the transistor, and perpendicular to the length of the transistor. The conductive gate layer 17 may include a notch in the width at either or both of the source side and drain side of the gate.

As an example, gate insulator layer 13 is local and does not extend over the entire surface of the upper side of semiconductor layer 11. As an example, gate insulator layer 13 is formed vertically in line with conductive gate layer 17. The length of gate insulator layer 13 is, for example, similar to that of the second portion 173 of conductive gate layer 17, for example equal to the length L3.

Semiconductor layer 11 is, for example, made of silicon, for example of single-crystal silicon. Semiconductor layer 11 has, for example, a thickness in the range from 10 nm to 500 nm, for example from 50 nm to 200 nm, for example in the order of 60 nm or in the order of 160 nm.

As an example, gate insulator layer 13 is made of silicon dioxide (SiO₂) and has, for example, a thickness e1 in the range from 1 nm and 15 nm, for example, in the range from 3 nm and 7 nm.

As an example, buried oxide layer 15 is made of oxide, for example of silicon dioxide (SiO₂). Buried insulating layer 15 has, for example, a thickness in the range from 100 nm to 400 nm, for example from 100 nm to 250 nm, for example in the order of 200 nm.

As an example, conductive gate layer 17 is etched in a single step, for example by modifying during the etching the bias parameters to form the notch. The first portion 171 and second portion 173 are, for example, identical by their compositions. As an example, conductive gate layer 17 is made of doped polysilicon.

As a variant, conductive gate layer 17 is etched in two successive steps, one enabling to form portion 171 and the other enabling to form portion 173. In this variant, the two portions 171 and 173 of conductive gate layer 17 are, for example, made of two different materials, for example one of the portions is based on polysilicon and the other is based on germanium-doped polysilicon.

Layer 17 has, for example, a thickness in the range from 30 nm to 300 nm, for example in the range from 50 nm to 100 nm, for example in the range from 80 nm to 90 nm. As an example, the portions 171 and 173 of conductive gate layer 17 have a length in the range from 50 nm to 300 nm, for example in the range from 100 nm to 200 nm. As an example, the portions 171 and 173 of conductive gate layer 17 have a length difference (corresponding to the depth of the notch) in the range from 5 nm to 40 nm, for example in the order of 10 nm. Conductive gate layer 17 has, for example, a width in the range from 1 μm to 10 μm, for example in the order of 5 μm.

Transistor 10 comprises, for example, a source region 21 and a drain region 23 formed in semiconductor layer 11. Source region 21 and drain region 23 are, for example, laterally separated from each other by a body region 22. An upper portion of body region 22 forms the channel-forming region 24 of transistor 10. Conductive gate layer 17 is, for example, located above channel-forming region 24.

As an example, the source region 21, drain region 23, and body region 22 are flush with the upper surface of semiconductor layer 11.

Transistor 10 is, for example, an N-channel MOS transistor (NMOS), that is, a transistor having N-type doped source 21 and drain 23 regions, for example doped with arsenic or phosphorus atoms, while the body region is P-type doped, for example doped with boron atoms.

As a variant, transistor 10 is, for example, a P-channel MOS transistor (PMOS) that is, a transistor having P-type doped source 21 and drain 23 regions, for example doped with boron atoms, while the body region is N-type doped, for example doped with arsenic or phosphorus atoms.

As an example, transistor 10 comprises an insulating layer 25 coating the sides of conductive gate layer 17 and the sides of gate insulator layer 13. As an example, insulating layer 25 coats and is in contact with a portion of the upper surface of semiconductor layer 11 located in the vicinity of gate insulator layer 13. Insulating layer 25 is, for example, made of oxide or of nitride. As an example, insulating layer 25 is made of silicon nitride (Si₃N₄).

As an example, the source 21 and drain 23 regions are topped with an insulating layer 27, in line with insulating layer 25. As an example, layer 27 is formed in contact with the upper surface of semiconductor layer 11. As an example, layer 27 is made of an oxide.

Transistor 10 further comprises spacers 29 comprising a lower portion 291 and an upper portion 293. As an example, a spacer 29 is formed on each of the lateral sides of conductive gate layer 17. Each spacer 29 is, for example, in contact, by a lateral side with the lateral side of insulating layer 25 and by its lower surface with the upper surface of the portion of insulating layer 25 formed on semiconductor layer 11. In each spacer 29, the lower portion 291 is made of a first dielectric material and the upper portion 293 is made of a second dielectric material, the first material having a Young's modulus greater than a Young's modulus of the second material. As an example, the first material of the lower portion 291 of spacer 29 has a relatively higher Young's modulus, for example greater than 200 GPa, for example greater than 250 GPa. As an example, the second material of the upper portion 293 of spacer 29 has a relatively lower Young's modulus, for example smaller than 100 GPa, for example smaller than 80 GPa.

As an example, the first material of the lower portion 291 of spacer 29 has a dielectric constant greater than a dielectric constant of the second material of the upper portion 293 of spacer 29. As an example, the first material of the lower portion 291 of spacer 29 has a relatively higher dielectric constant, for example greater than 7, for example greater than 8. As an example, the second material of the upper portion 293 of spacer 29 has a relatively lower dielectric constant, for example smaller than 5, for example smaller than 4. By dielectric constant of a material, there is here meant the ratio of the permittivity of the material to the permittivity of vacuum.

As an example, the first material is made of a nitride, for example of aluminum nitride. As an example, the first material is made of silicon carbide. As an example, the first material is made of diamond. As an example, the first material may be made of tungsten carbide, of silicon carbide, of aluminum oxide, of beryllium oxide, of silicon nitride, of magnesium oxide, of zirconium oxide, of silicon, of aluminum silicate, of silicon oxide, of borophosphosilicate glass, of borosilicate glass, of phosphosilicate glass, of fluorosilicate glass, and/or of non-doped silicate glass.

As an example, the second material is made of tetraethylorthosilicate (TEOS). As an example, the second material is made of phosphosilicate glass. As an example, the second material is made of silicoboron carbonitride (SiBCN). As an example, the second material is made of silicon oxide, of organosilicate glass, of polyimide, of borophosphosilicate glass, of borosilicate glass, of phosphosilicate glass, of fluorosilicate glass, and/or of non-doped silicate glass.

The lower portion 291 thus covers a lower portion of conductive gate layer 17 and the upper portion 293 covers an upper portion of conductive gate layer 17. In FIG. 1, spacer 29 has been shown so that the lower portion 291 of stack 29 covers the first portion 171 of conductive gate layer 17 and the upper portion 293 covers the second portion 173 of conductive gate layer 17. In other words, the interface between the lower portion 291 and upper portion 293 of spacer 29 is located at the level of the upper wall of the notch formed in gate 17.

As a variant, the lower portion 291 of spacer 29 may cover a portion of the second portion 173 of conductive gate layer 17. Still as a variant, the upper portion 293 of spacer 29 may cover part of the first portion 171 of conductive gate layer 17.

Transistor 10 further comprises an insulating layer 31 coating the sides of spacer 29. As an example, the insulating layer 31 covers the sides of spacer 29 which are not covered with insulating layer 25 and the upper surface of layer 27. As an example, insulating layer 31 is open in front of the upper surface of conductive gate layer 17 to be able to recover the contact therein. Insulating layer 31 is, for example, made of silicon nitride.

Transistors 10 are advantageously capable of operation as RF switches, for example intended to operate at frequencies in the range from 3 kHz to 300 GHz, for example from 100 MHz to 10 GHz, for example in the order of one GHz. In such an RF switching application, the operating parameters desired are for a low parasitic off-state capacitance C_{OFF} of the transistor and a low on-state resistance R_{ON} of the transistor.

In transistor 10, capacitance C_{OFF} is influenced by the parasitic capacitances between the gate and the source and drain contacts which are themselves controlled by the dielectric constants of the spacers. Still in transistor 10, resistance R_{ON} is influenced by the mobility of charge carriers, itself controlled by the mechanical stress applied to channel region 24.

An advantage of the present embodiment is that spacer 29 enables to favor the transmission of mechanical stress, for example introduced by insulating layer 31, to channel region 24, and this due to the provision of a material having a relatively high Young's modulus located in the notch formed in the lower portion of the gate. This particularly enables to decrease the resistance R_{ON} of the switch.

Another advantage of the present embodiment is that the provision of a material having a relatively high dielectric constant in the lower portion of the spacer and in particular in the notch formed in the lower portion of the gate enables to decrease the capacitance C_{OFF} of the switch.

This embodiment thus enables to optimize the R_{ON} and C_{OFF} tradeoff for the RF switch, due to an increased transfer of stress to the channel and to decreased capacitances.

FIG. 2 is a cross-section view partially and schematically illustrating a transistor 10′ according to a second embodiment.

The transistor 10′ illustrated in FIG. 2 is similar to the transistor 10 illustrated in FIG. 1, with the difference that transistor 10′ does not comprise insulating layer 25. In the embodiment illustrated in FIG. 2, the lateral sides of conductive gate layer 17 are covered with spacer 29, formed in contact with conductive gate layer 17.

In the foregoing embodiments, transistors 10 and 10′ comprise a layer 27 coating the upper surface of semiconductor layer 11, but this layer 27 may be omitted. Additionally, the lower portion 291 and upper portion 293 may be formed in a manner where upper portion 293 covers lower portion 291 so that layer 31 is not in contact with lower portion 291. Indeed, such a configuration could include an arrangement where the material of the lower portion 291 is contained only within the notch associate with length L1.

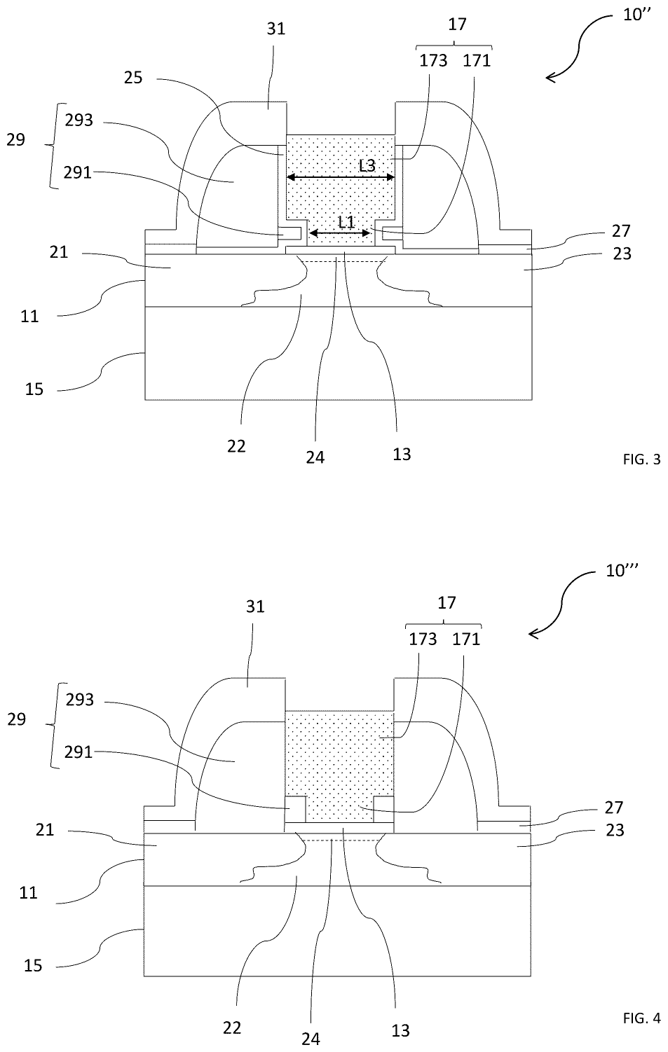

FIG. 3 is a cross-section view partially and schematically illustrating a transistor 10″ according to a third embodiment.

The transistor 10″ illustrated in FIG. 3 is similar to the transistor 10 illustrated in FIG. 1, with the difference that the material 291 of higher Young's modulus is located only in the notch formed in the conductive gate 17. In this embodiment, the material 293 of lower Young's modulus may extend vertically along the entire height of the conductive gate 17. In this embodiment, the interface between the material 291 and the material 293 is vertical (not horizontal as in the embodiment of FIG. 1). In this embodiment, the material of higher Young's modulus 291 is not in contact with insulating layer 31.

FIG. 4 is a cross-section view partially and schematically illustrating a transistor 10′″ according to a fourth embodiment.

The transistor 10′″ illustrated in FIG. 4 is similar to the transistor 10″ illustrated in FIG. 3, with the difference that transistor 10′″ does not comprise insulating layer 25.

Various embodiments and variants have been described. Those skilled in the art will understand that certain features of these various embodiments and variants may be combined, and other variants will occur to those skilled in the art. In the foregoing embodiments, transistors 10, 10′, 10″, and 10′″ comprise a layer 27 coating the upper surface of semiconductor layer 11, but this layer 27 may be omitted. Further, the described embodiments are not limited to the examples of materials and of dimensions mentioned in the present disclosure.

Finally, the practical implementation of the described embodiments and variants is within the abilities of those skilled in the art based on the functional indications given hereabove.

1. A transistor, comprising:
a semiconductor layer;
a stack comprising a gate insulator layer and a conductive gate over the semiconductor layer;
wherein a length of the conductive gate is smaller on a side of a lower surface of the conductive gate, located in a vicinity of the gate insulator layer, and is greater on a side of an upper surface of the conductive gate, said upper surface being opposite to the lower surface; and
a spacer structure adjacent lateral sides of the conductive gate, said spacer structure comprising a first material at a lower portion of the conductive gate where the length of the conductive gate is smaller, and a second material at an upper portion of the conductive gate where the length of the conductive gate is greater;
wherein the first material has a Young's modulus greater than a Young's modulus of the second material.

2. The transistor according to claim 1, wherein the Young's modulus of the first material is greater than 200 GPa.

3. The transistor according to claim 1, wherein the Young's modulus of the second material is smaller than 100 GPa.

4. The transistor according to claim 1, wherein the first material has a dielectric constant greater than a dielectric constant of the second material.

5. The transistor according to claim 4, wherein the dielectric constant of the first material is greater than 7.

6. The transistor according to claim 4, wherein the dielectric constant of the second material is smaller than 4.

7. The transistor according to claim 1, wherein the conductive gate comprises a notch extending across its entire width at the side of the lower surface.

8. The transistor according to claim 7, wherein a difference between a length of the conductive gate at the side of the lower surface and a length of the conductive gate at the side of the upper surface on the upper surface is in a range from 5 nm to 40 nm.

9. The transistor according to claim 7, wherein the first material of the spacer fills the notch.

10. The transistor according to claim 1, wherein the first material is based on a material selected from the group consisting of: a nitride, a carbide, or diamond.

11. The transistor according to claim 1, wherein the second material is based on a material selected from the group consisting of: tetraethyl-orthosilicate, phosphosilicate glass, or silicoboron carbonitride.

12. The transistor of according to claim 1, wherein the conductive gate comprises a first portion defined by the length smaller on the side of the lower surface made of a first gate material and a second portion defined by the length greater on the side of the upper surface made of a second gate material, wherein the second gate material is different from the first gate material.

13. The transistor of according to claim 12, wherein the first gate material is made of polysilicon and the second gate material is made of germanium-doped polysilicon.

14. The transistor according to claim 12, wherein a thickness of the first portion of the conductive gate is equal to a thickness of a portion of the spacer structure made of the first material.

15. The transistor according to claim 14, wherein a thickness of the second portion of the conductive gate is greater than a thickness of a portion of the spacer structure made of the second material.

16. The transistor according to claim 12, wherein a thickness of the first portion of the conductive gate is less than a thickness of a portion of the spacer structure made of the first material.

17. The transistor according to claim 16, wherein a thickness of the second portion of the conductive gate is greater than a thickness of a portion of the spacer structure made of the second material.

18. The transistor according to claim 1, further comprising an insulating liner extending along a side surface of the conductive gate and on an upper surface of the gate insulator layer in a notch region where the length of the conductive gate is smaller on the side of the lower surface of the conductive gate.

19. The transistor according to claim 1, wherein said length of the conductive gate being smaller on the side of the lower surface of the conductive gate, and greater on the side of the upper surface of the conductive gate forms a notch, and wherein a separation between the first material and the second material is located at a level of an upper wall of the notch in the conductive gate.

20. The transistor according to claim 19, wherein the notch in the conductive gate extends across its the entire width of the conductive gate at the side of the lower surface.

21. The transistor according to claim 19, wherein the first material is located only in the notch formed in the conductive gate layer.

22. A radio frequency switch, comprising a transistor according to claim 1.
